(19) United States
(12) Patent Application Publication
(10) Pub. No.: US 2005/0252642 A1
(43) Pub. Date: Nov. 17, 2005

(54) Finned heat dissipation module with smooth guiding structure

(76) Inventor: Juei-Chi Chang, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/090,178

(22) Filed: Mar. 28, 2005

(30) Foreign Application Priority Data
May 13, 2004 (TW) 93113429

(51) Int. Cl. H05K 7/20

(52) U.S. Cl. 165/80.3; 361/704

(57) ABSTRACT

A heat dissipation module includes an airflow generation device that generates airflow into an air channel in which a fin module is received and fixed. The fin module includes a plurality of fin plates substantially parallel to and spaced from each other to define air passages extending from an inlet to an outlet of the air channel. Each fin plate has a leading section extending from the inlet and a trailing section extending from the leading section to the outlet. The front end of the leading section is formed with a curved shape guiding head for receiving the airflow. The guiding head generally extends along the same moving direction as the airflow, such that air flows in smoothly via the guiding head to the air passage.

### FIELD OF THE INVENTION

The present invention relates generally to a heat dissipation module comprising fins, and in particular to a finned heat dissipation module having smooth guiding structure.

### BACKGROUND OF THE INVENTION

The development of computer technology makes the power consumption of a computer device dramatically increased. Thus, a heat dissipation module is commonly employed in the recent computer devices or other electronic devices to remove heat from the computer devices or electronic components that generate heat in order to maintain proper operation temperature of the computer or electronic devices. Some heat dissipation devices incorporate a fan that induces air streams flowing through the heat dissipation device to facilitate heat removal by forced heat convection.

Factors that are often taken into consideration for overcoming heat removal problem include performance of the computer components, which leads to reduced energy consumption and generates less heat during the operation thereof, and geometric configuration, which enhances heat exchange rate between the heat generation component and a heat dissipation device for more efficient removal of heat.

A state-of-art heat dissipation module, generally employed in a notebook computer that requires more severe heat management than regular desktop computers, comprises a thermally conductive casing in physical contact with a surface of a heat source, such as a central processing unit of a notebook computer. The casing forms a fan chamber in which a fan is received and fixed and an air channel in which a plurality of fins is arranged to define a plurality of air passages through which airflow from the fan may pass to initiate heat exchange with the fins and thus removing heat from the fins, as well as the casing.

It is found that the conventional heat dissipation modules cannot efficiently remove heat from the computer devices. Furthermore, some of the heat dissipation modules are arranged in a manner that they have to directly or indirectly contact the heat sources so as to enhance heat removal therefrom. Accordingly, their structures are complicated.

FIG. 1 of the attached drawings show an example of the conventional heat dissipation module housed in a casing. As mentioned above, the air channel of the heat dissipation module comprises a plurality of fin plates 100 parallel to each other to define a plurality of air passages 103 therebetween, each air passage extending from an inlet 101 to an outlet 102. Airflow generated by a fan often moves in a direction that is not parallel to the passages 103. Thus, when an airflow 104 generated by a fan (not shown) enters the inlet 101, the airflow 104 goes in an oblique direction and impacts the inner surface of the fin plate 100, which imparts a resistance to the airflow, causing a turbulence 105a. Also, a secondary turbulence 105b is formed by the airflow reflected by the fin plate 100 to hit an adjacent fin plate. The turbulences 105a, 105b are then combined in a downstream location, forming a substantially unified air stream 105 that passes through the air passage 103.

Although heat can be effectively carried out by the heat dissipation module described above, the heat dissipation module cannot offer the optimum efficiency in removing heat and usually makes great noises.

Thus, the present invention is aimed to provide a heat dissipation module that overcomes at least some of the drawbacks of the conventional devices.

### SUMMARY OF THE INVENTION

An object of the present invention is to provide a heat dissipation module with improved fin plate structure. The fin plates are formed with guiding heads for inducing smooth and steady airflow to the air passages between fin plates, that results in enhanced heat removal.

Another object of the present invention is to provide a finned heat dissipation module with smooth guiding structure. The guiding structure highly reduces the resistance to the air flowing therethrough, and thereby reducing noises and enhancing heat exchange between the fin plates and the air.

To achieve the above objects, in accordance with the present invention, there is provided a heat dissipation module. The heat dissipation module includes an airflow generation device that generates airflow into an air channel in which a fin module is received and fixed. The fin module includes a plurality of fin plates substantially parallel to and spaced from each other to define air passages extending from an inlet to an outlet of the air channel. Each fin plate has a leading section extending from the inlet and a trailing section extending from the leading section to the outlet. The front end of the leading section is formed with a curved shape guiding head for receiving the airflow. The guiding head generally extends along the same moving direction as the airflow, such that air flows in smoothly via the guiding head to the air passage.

### BRIEF DESCRIPTION OF THE DRAWINGS

The present invention will be apparent to those skilled in the art by reading the following description of preferred embodiments thereof, with reference to the attached drawings, in which:

FIG. 1 is a cross-sectional view of an air channel of a conventional heat dissipation module;

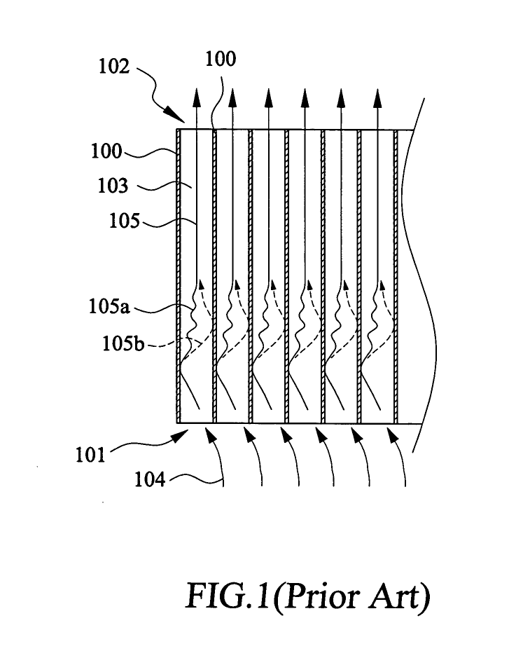

FIG. 2 is an exploded view of a heat dissipation module constructed in accordance with the present invention;

FIG. 3 is a perspective view showing the spatial relationship between the heat dissipation module of the present invention and a heat-generating electronic device mounted on a circuit board;

FIG. 4 is a perspective view of the heat dissipation module of the present invention;

FIG. 5 is a perspective view of an air channel structure incorporated in the heat dissipation module of the present invention;

FIG. 6 is an exploded view of the air channel of the present invention; and

FIG. 7 is a cross-sectional view showing the movement of air from the fan to the air channel of the present invention.

### DETAILED DESCRIPTION OF PREFERRED EMBODIMENTS

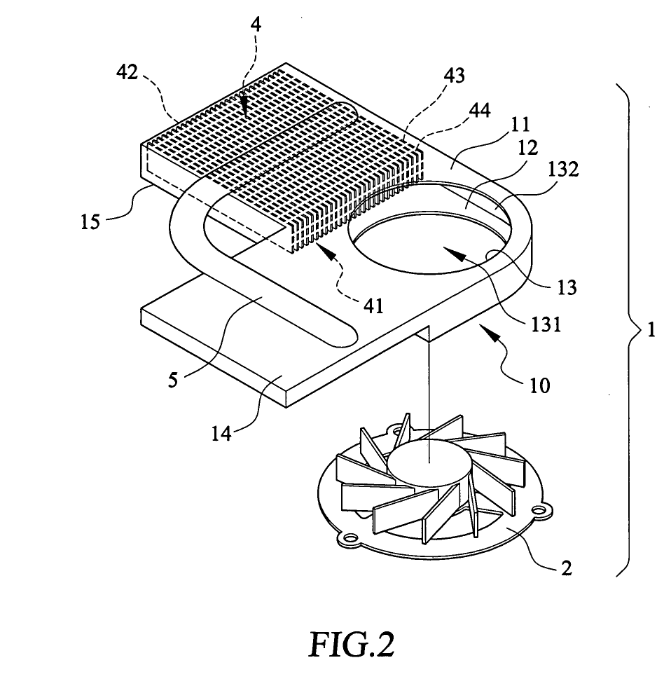

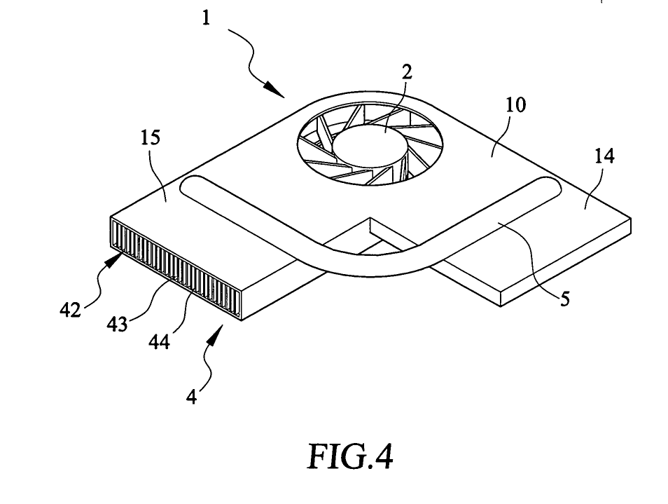

With reference to the drawings and in particular to FIGS. 2 and 4, a heat dissipation module constructed in accordance with the present invention, generally designated with reference numeral 1, comprises a casing or cartridge 10 made of thermally conductive material, comprised of a top panel 11 and a bottom panel 12 opposite to the top panel 11 with an interior space defined between the top and bottom panels 11, 12. Aligned openings (not labeled) are defined in the top and bottom panels 11, 12 to form a fan chamber 13 that receives and fixes an electric fan 2. The opening defined in the top panel for the fan 2 also constitutes an air intake opening 131 through which surrounding air may be drawn into the interior space of the casing 10 by the fan 2. A side opening 132 formed between outer edges of the top and bottom panels 11, 12 also provides an intake entrance for surrounding air into the interior space of the casing 10 by being drawn by the fan 2.

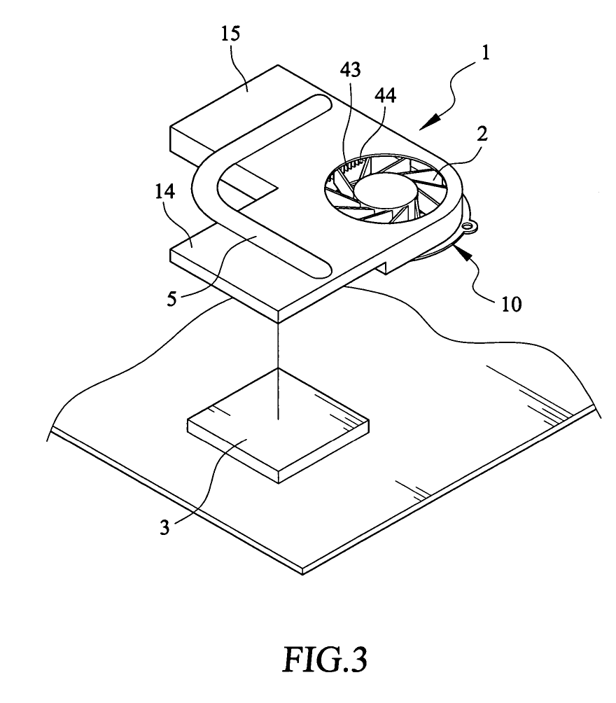

Also referring to FIG. 3, a lateral extension of the casing 10 forms a device contact section 14 having a surface positionable on and physically engageable with a heat-generating device 3, such as electronic device mounted on a circuit board, a computer central processing unit or integrated circuits. Through heat transfer induced by conduction, heat is transmitted from the heat-generating device 3 to the device contact section 14 of the casing 10 and further transmitted to other portions of the casing 10.

The casing 10 also forms an air channel 15 substantially extending in a radial direction from the fan chamber 13. Arranged in the air channel 15 is a fin module 4 having an inner end forming an airflow inlet 41 adjacent to the fan 2 and an opposite outer end forming an airflow outlet 42 away from the fan 2.

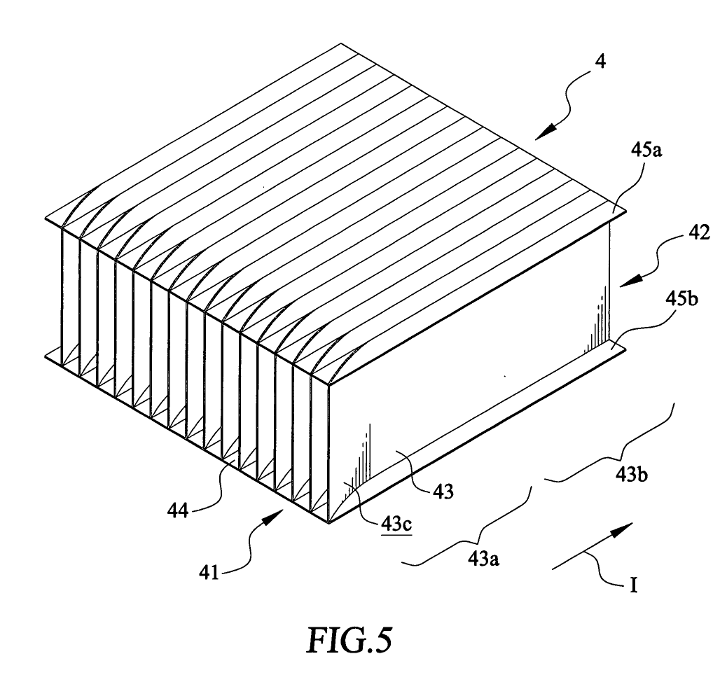

Also referring to FIGS. 5-7, the fin module 4 is comprised of a plurality of fin plates 43 substantially parallel to and spaced from each other to define air passages 44 therebetween. The fin plates 43 are fixed inside the air channel 15 and in physical engagement with the portion of the casing 10 that constitutes the air channel 15. The fin plates 43 extend in a direction from the airflow inlet 41 to the airflow outlet 42 for guiding airflow from the airflow inlet 41 to the airflow outlet 42. Airflow 6 passing through each air passage 44 gets in contact with surfaces of the fin plates 42 on opposite sides of the air passage 44 and initiates heat exchange therewith by forced convection. Thus heat transmitted from the heat-generating device 3 to the casing 10 is removed by the airflow 6 passing through the air passage 44.

Optionally, a heat pipe 5 is mounted between the device contact section 14 of the casing 10 and the air channel 15 for facilitating heat transfer from the device contact section 14 to the air channel 15 to thereby enhance heat removal.

The fin plates 43 extend from the airflow inlet 41 to the airflow outlet 42 of the air channel 15, in which the fin plates substantially extend along a first direction I for a predetermined distance. Each fin plate 43 comprises a leading section 43a extending from the airflow inlet 41 and a trailing section 43b in the proximity of the airflow outlet 42. Air is guided to flow from the airflow inlet 41 through the leading sections 43a to the air passages 44 between the fin plates 43. Then air flows out from the airflow outlet 42 through the trailing sections 43b.

Each fin plate 43 comprises top and bottom flanges 45a, 45b substantially perpendicular to a web (not labeled) of the fin plate 43 for spacing adjacent fin plates 43 to form the air passage 44 between the adjacent fin plates 43. The flanges 45a, 45b may be optionally dimensioned to physically engage the top and bottom panels 11, 12 of the casing 10 for heat transfer and fixing purposes, otherwise means for transferring heat between the casing 10 and the fin plates 43 may be employed.

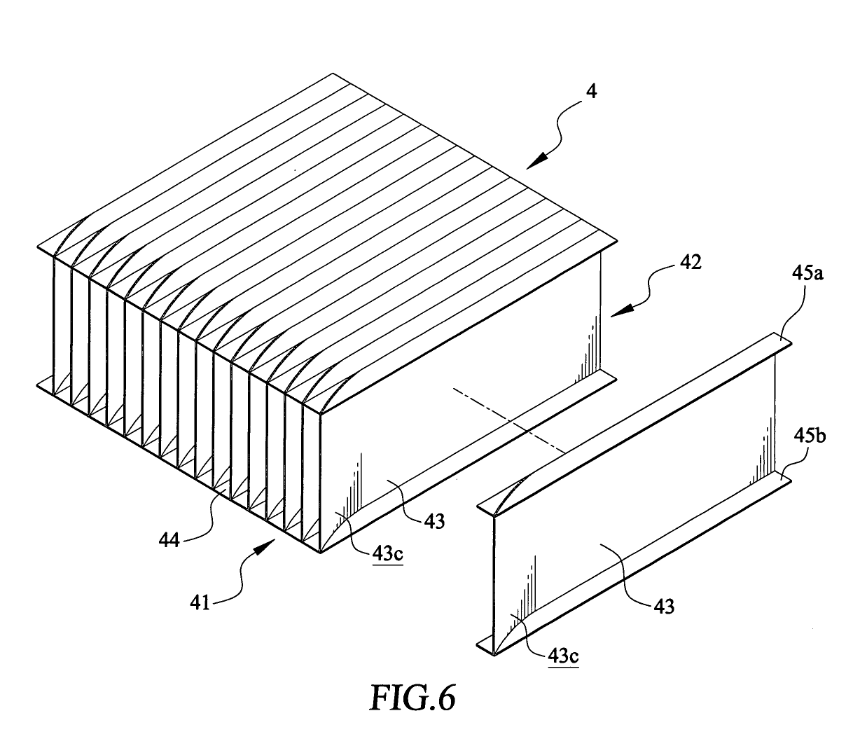

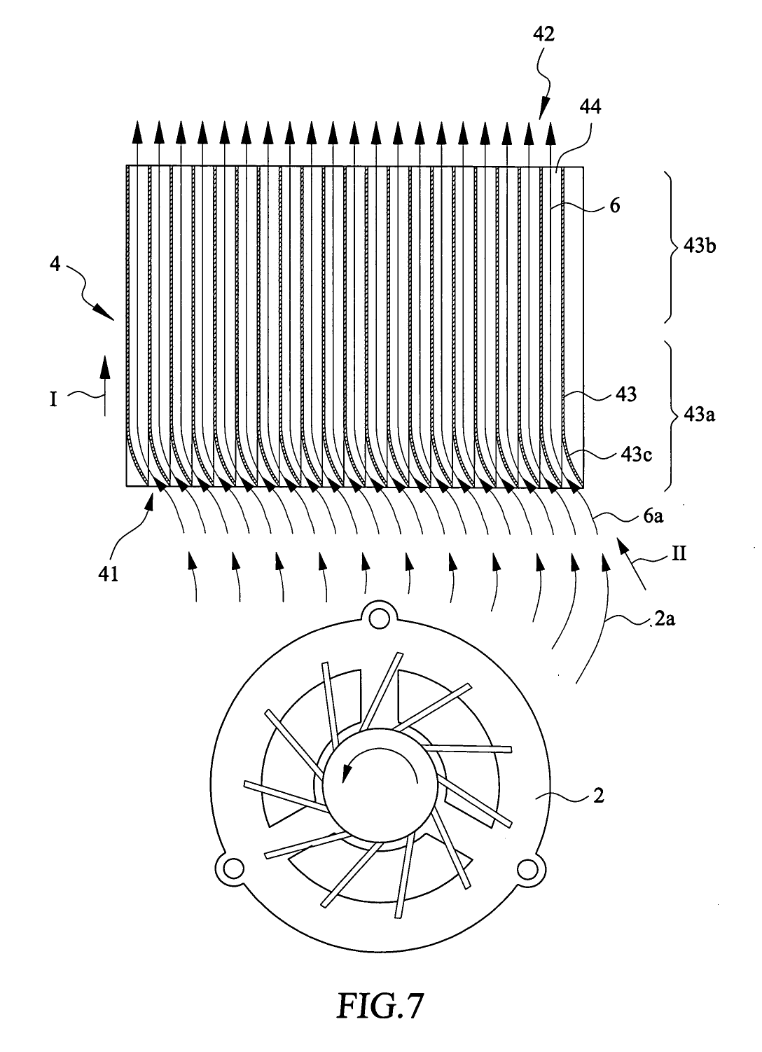

When the fan 2 operates, the blades of the fan 2 rotate and generate an airflow 2a. Due to inertia, the airflow 2a flows in a helical manner. The airflow 2a moves to the leading section 43a along a second direction II, forming an airflow 6a. The second direction II is substantially identical to the tangential line (not shown) of the airflow 6a. As shown in FIGS. 6 and 7, the front end of each leading section 43a of the fin plate 43 is formed with a curved shape guiding head 43c extending generally along the second direction II. By means of the arrangement of the guiding heads 43c, the air passages between guiding heads are orientated to receive the component 6a. Thereby, the airflow 6a flows smoothly along guiding heads 43c to the leading sections 43a and air passages 44, and then flows out from airflow outlet 42.

For the conventional fin plates without guiding structure, when the airflow enters the inlet, the air goes in an oblique direction and impacts the surfaces of the fin plates, which imparts a resistance to the airflow and causes noises. By using the guiding heads, the air flows smoothly to the leading sections and flows along the air passages. Obviously, resistance to the airflow is significantly reduced, and efficiency of the heat dissipation module is enhanced.

Although the present invention has been described with reference to the preferred embodiments thereof, it is apparent to those skilled in the art that a variety of modifications and changes may be made without departing from the scope of the present invention which is intended to be defined by the appended claims.

1. A heat dissipation module comprising:
an airflow generation device that generates an airflow;
an air channel having an inlet receiving the airflow and an opposite outlet;
a fin module received and fixed in the air channel between the inlet and the outlet for guiding the airflow from the inlet through the air channel to the outlet, the fin module comprising a plurality of fin plates substantially parallel to and spaced from each other to define therebetween air passages through each of which the airflow passes, each fin plate comprising:
a leading section extending from the inlet, which is formed with a curved shape guiding head at a front end of the leading section for receiving the airflow, in which the guiding head extends along a moving direction of the airflow towards the leading section, such that air flows smoothly via the guiding head to the air passage; and
a trailing section extending from the leading section to the outlet.

2. The heat dissipation module as claimed in claim 1, wherein each fin plate comprises a web having top and bottom edges from which top and bottom flanges extend, respectively, for spacing adjacent fin plates to form the air passages therebetween.

3. The heat dissipation module as claimed in claim 1, wherein the airflow generation device comprises a fan, in which the inlet of the air channel is adjacent to and faces to the fan.

4. A heat dissipation module comprising:
a casing comprising top and bottom panels spaced from each other to define an interior space therebetween, aligned openings being defined in the top and bottom panels to form a fan chamber;
a fan received and fixed in the fan chamber to generate an airflow;
an air channel extending from the air chamber and having an inlet adjacent to the air chamber to receive the airflow and an opposite outlet;
a fin module received and fixed in the air channel between the inlet and the outlet and comprising a plurality of fin plates substantially parallel to and spaced from each other to define therebetween air passages extending from the inlet to the outlet, each fin plate comprising:
a leading section extending from the inlet, which is formed with a curved shape guiding head at the front end of the leading section for receiving the airflow, in which the guiding head extends along a moving direction of the airflow towards the leading section, such that air flows in smoothly via the guiding head to the air passage; and
a trailing section extending from the leading section to the outlet.

5. The heat dissipation module as claimed in claim 4, wherein each fin plate comprises a web having top and bottom edges from which top and bottom flanges extend, respectively, for spacing adjacent fin plates to form the air passages.

6. The heat dissipation module as claimed in claim 4, further comprising a heat pipe which is mounted on the casing.

7. The heat dissipation module as claimed in claim 4, wherein the front end of the guiding head extends along a direction which is identical to the tangential line of the airflow moving towards the leading section.
